(19) United States
(12) Patent Application Publication
(10) Pub. No.: US 2023/0307412 A1
(43) Pub. Date: Sep. 28, 2023

(54) SEMICONDUCTOR STRUCTURE AND METHOD OF MANUFACTURING THE SAME

(71) Applicant: Taiwan Semiconductor Manufacturing Company, Ltd., Hsinchu (TW)

(72) Inventor: Jen-Yuan Chang, Hsinchu City (TW)

(21) Appl. No.: 17/858,387

(22) Filed: Jul. 6, 2022

Related U.S. Application Data
(60) Provisional application No. 63/313,949, filed on Feb. 25, 2022.

(51) Int. Cl. H01L 23/00

(52) U.S. Cl. CPC H01L 24/80; H01L 24/05; H01L 24/06; H01L 24/08; H01L 23/585; H01L 2224/06517; H01L 2224/08145; H01L 2224/74; H01L 2224/8013

(57) ABSTRACT

A method of manufacturing a semiconductor structure includes following operations: moving a die towards a wafer by a pick-and-place tool, the pick-and-place tool including an infrared (IR) detection device attached to the pick-and-place tool in a fixed relationship; aligning the die with the wafer by using the IR detection device; and bonding the die to the wafer.

### REFERENCE TO RELATED APPLICATION

This Application claims the benefit of U.S. Provisional Application No. 63/313,949, filed on Feb. 25, 2022, the contents of which are hereby incorporated by reference in their entirety.

### BACKGROUND

The manufacturing of integrated circuits often involves bonding dies to wafers or package substrates. In a typical bonding process, a bond head picks up a die and then places the die on a wafer or package substrate. After a plurality of dies are placed on a wafer or a package substrate, a reflow process is performed, so that the dies are bonded to the wafers or package substrates. The accuracy in the placement of the die on the wafer or package substrate needs to be well controlled to maintain the yield of the bonding process.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1F are schematic views of intermediate stages of a method of manufacturing a semiconductor structure in accordance with some embodiments of the present disclosure.

FIGS. 2A to 2K are top views of arrangements of alignment marks in accordance with some embodiments of the present disclosure.

FIG. 3A is a top view of an arrangement of alignment marks in accordance with some embodiments of the present disclosure.

FIGS. 3B to 3D are schematic views of arrangements of alignment marks in accordance with some embodiments of the present disclosure.

FIG. 4 is a schematic view of one or more intermediate stages of a method of manufacturing a semiconductor structure in accordance with some embodiments of the present disclosure.

FIG. 5 is a schematic view of one or more intermediate stages of a method of manufacturing a semiconductor structure in accordance with some embodiments of the present disclosure.

FIG. 6 is a cross-sectional view of a semiconductor structure in accordance with some embodiments of the present disclosure.

FIG. 6A is a cross-sectional view of a semiconductor structure in accordance with some embodiments of the present disclosure.

FIG. 6B is a cross-sectional view of a semiconductor structure in accordance with some embodiments of the present disclosure.

FIG. 6C is a cross-sectional view of a semiconductor structure in accordance with some embodiments of the present disclosure.

FIG. 7 is a cross-sectional view of a semiconductor structure in accordance with some embodiments of the present disclosure.

FIG. 7A is a cross-sectional view of a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Embodiments of the present disclosure discuss a method of manufacturing a semiconductor structure including aligning a die with a wafer by using an infrared (IR) detection device installed on a pick-and-place tool and then bonding the die to the wafer by the pick-and-place tool. Therefore, the alignment of the die with the wafer can be performed in the process of the die being moved towards the wafer by the pick-and-place tool, the time used to move an external optical detector in and out of a detection location between the die and the wafer for alignment can be saved, and thus the efficiency and the throughput of the bonding process of the die and the wafer can be improved.

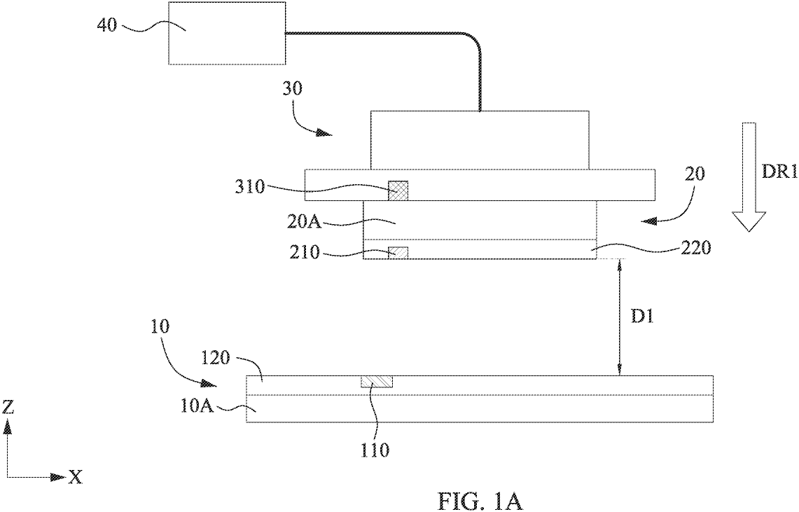

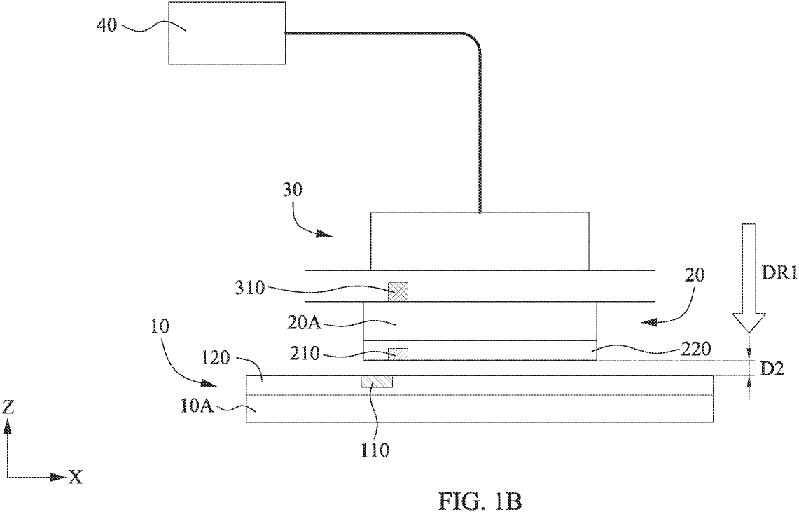

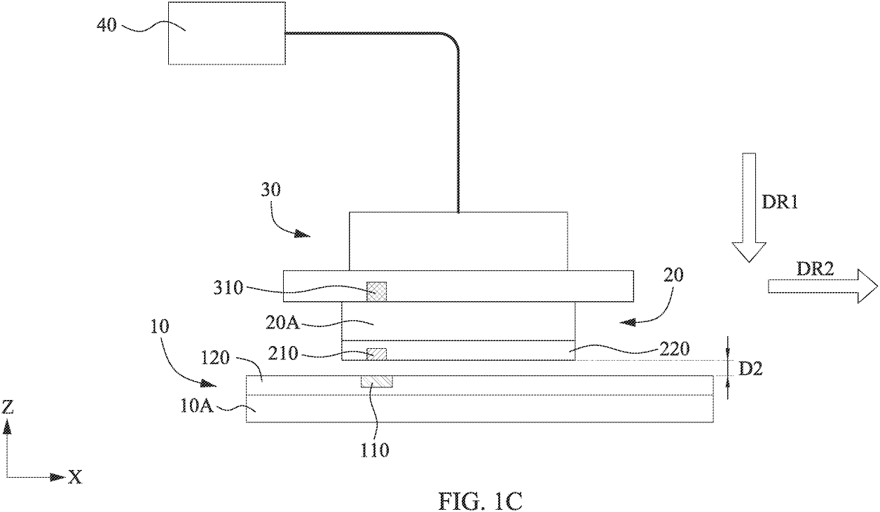

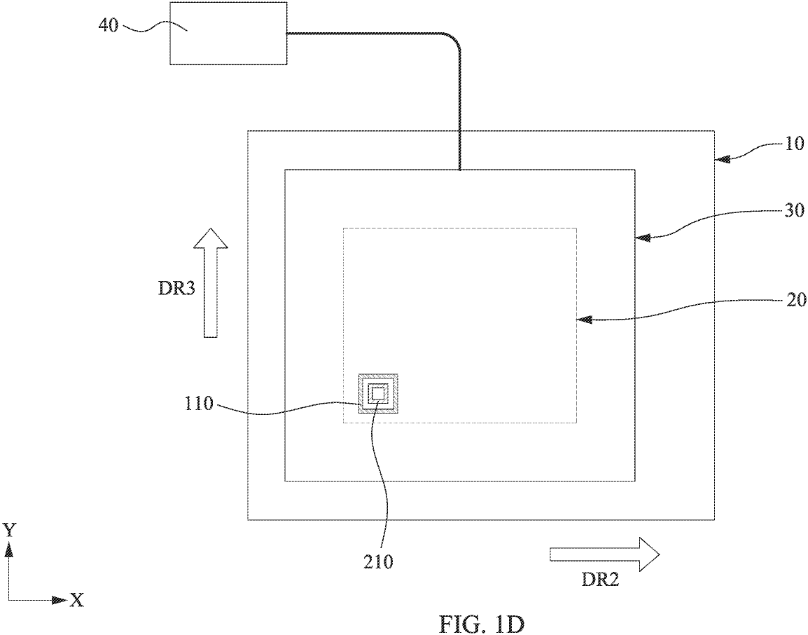

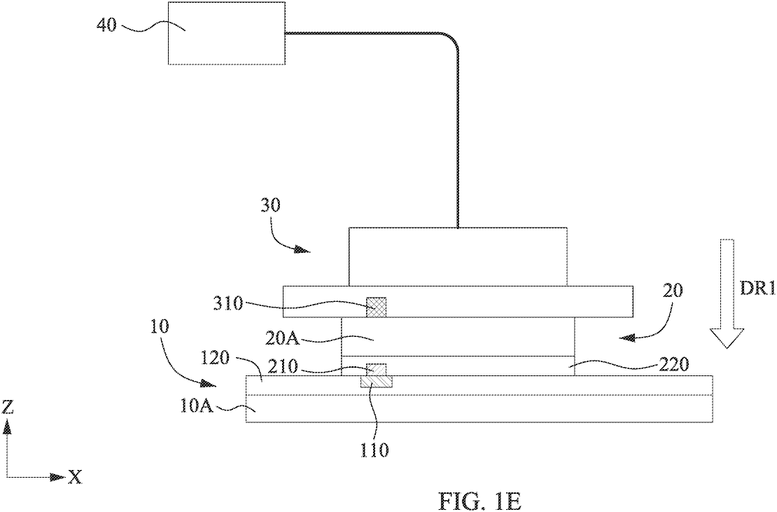

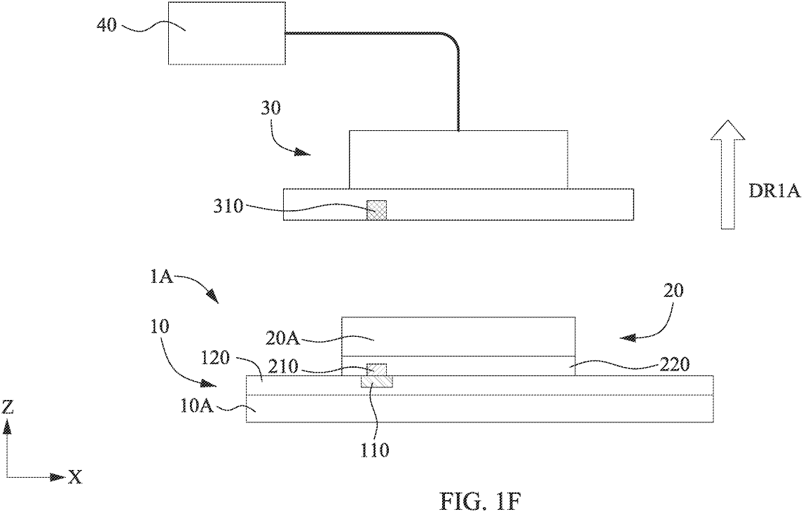

FIGS. 1A to 1F are schematic views of intermediate stages of a method of manufacturing a semiconductor structure in accordance with some embodiments of the present disclosure.

Referring to FIG. 1A, a pick-and-place tool 30 may be provided, and a die 20 may be moved by the pick-and-place tool 30 towards a wafer 10 at an initial speed V1 (also referred to as “a first speed”). In some embodiments, the die 20 is moved by the pick-and-place tool 30 in a direction of arrow DR1 (e.g., in a Z-axis). In some embodiments, the die 20 starts moving from an initial position which is separated from the wafer 10 by a distance D1.

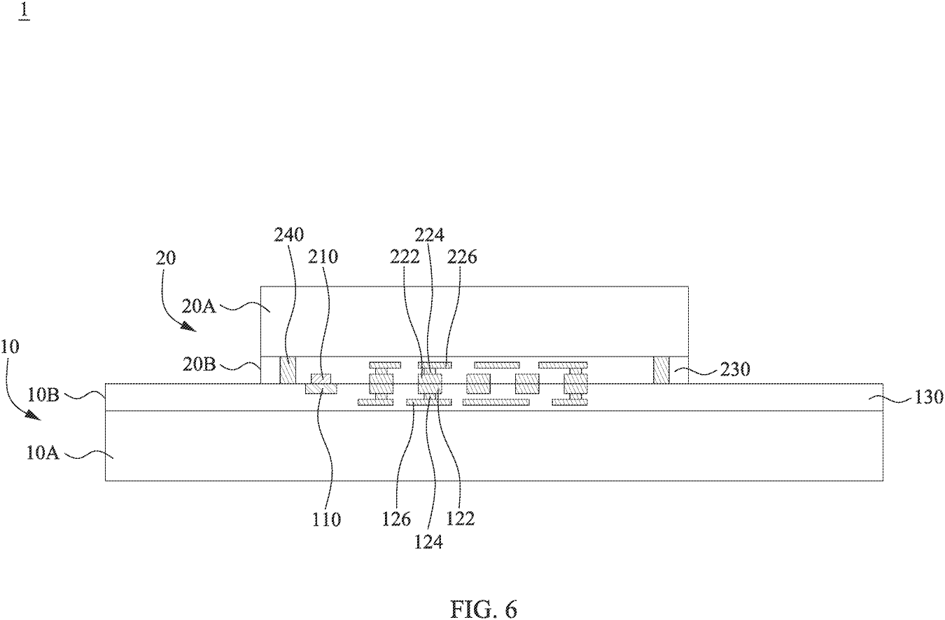

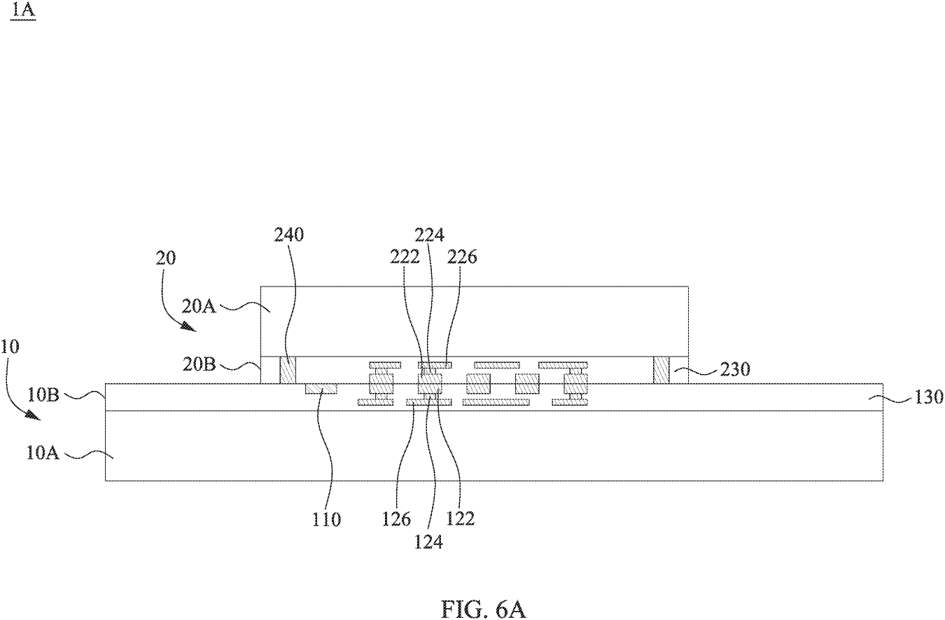

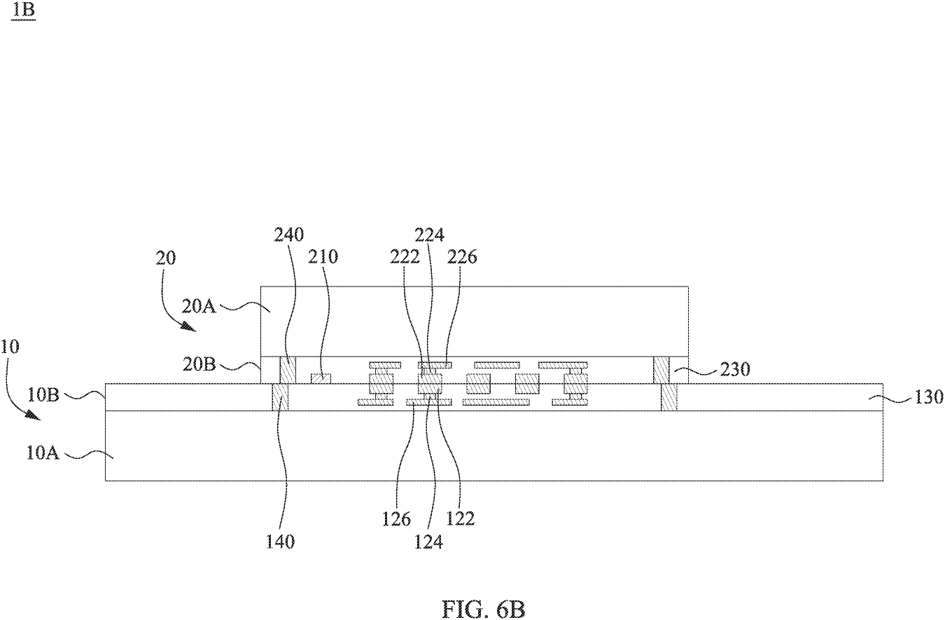

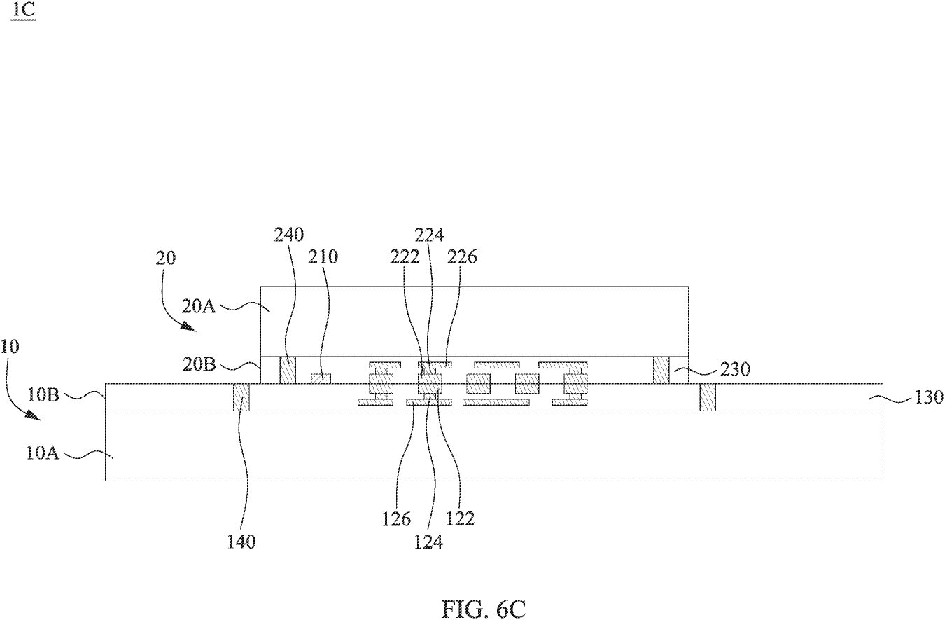

The wafer 10 may be or include a package substrate or a package substrate strip including a plurality of package substrates. In some embodiments, the wafer 10 may be or include a device structure including one or more devices in one or more package structures. In some embodiments, the wafer 10 includes a semiconductor substrate 10A, one or more alignment marks 110, and a bonding layer 120. The bonding layer 120 may include bonding pads (e.g., bonding pads 122 as shown in FIG. 6) having a size of equal to or less than about 2.5 µm, about 2 µm to about 2.5 µm, or equal to or less than about 0.5 µm. In some embodiments, the one or more alignment marks 110 are in the bonding layer 120. In some embodiments, the alignment mark 110 includes metal. The metal may be configured to reflect IR light. The alignment mark 110 may include copper (Cu), aluminum (Al), gold (Au), or any other suitable materials configured to reflect IR light that are within the contemplated scope of the disclosure. In some embodiments, the alignment mark 110 includes a two-dimensional (2D) pattern in an X-Y plane. In some embodiments, the alignment mark 110 includes one or more dummy metal patterns (e.g., a metal pattern that is not coupled to an active semiconductor device). In some embodiments, the alignment mark 110 includes a rectangular shape pattern, a polygonal shape pattern, an irregular shape pattern, a frame pattern, a pattern formed of a plurality of lines angled with each other, or a combination thereof. In some embodiments, a size of the alignment marks 110 may be equal to or less than about 2.5 µm, about 2 µm to about 2.5 µm, or equal to or less than about 0.5 µm.

In some embodiments, the semiconductor substrate 10A may include silicon (Si), germanium (Ge), silicon germanium (SiGe), silicon carbide (SiC), or other semiconductor materials. The semiconductor substrate 10A may be a bulk substrate or constructed as a semiconductor on an insulator (SOI) substrate. The semiconductor substrate 10A may include a redistribution layer (RDL), a dielectric structure, or a combination thereof. The RDL may include conductive layers and/or conductive vias. The bonding layer 120 may be configured to be hybrid-bonded or fusion-bonded to another bonding layer. In some embodiments, the bonding layer 120 includes silicon oxide, silicon oxynitride, or any suitable materials configured for hybrid bonding or fusion bonding. In some embodiments, the bonding layer 120 includes an RDL including conductive layers and/or conductive vias. The RDL of the bonding layer 120 may include the one or more alignment marks 110.

The die 20 may be or include one or more integrated circuit devices such as transistors, diodes, resistors, capacitors, and/or the like. In some embodiments, the die 20 may be or include a device structure including one or more devices. In some embodiments, the die 20 includes a semiconductor substrate 20A, one or more alignment marks 210, and a bonding layer 220. The bonding layer 220 may include bonding pads (e.g., bonding pads 222 as shown in FIG. 6) having a size of equal to or less than about 2.5 µm, about 2 µm to about 2.5 µm, or equal to or less than about 0.5 µm. In some embodiments, the one or more alignment marks 210 are in the bonding layer 220. In some embodiments, the alignment mark 210 includes metal. The metal may be configured to reflect IR light. The alignment mark 210 may include Cu, Al, Au, or any other suitable materials configured to reflect IR light that are within the contemplated scope of the disclosure. In some embodiments, the alignment mark 210 includes a dummy metal pattern. In some embodiments, the alignment mark 210 includes a 2D pattern in the X-Y plane. In some embodiments, the alignment mark 210 includes a rectangular shape pattern, a polygonal shape pattern, an irregular shape pattern, a frame pattern, a pattern formed of a plurality of lines angled with each other, or a combination thereof. In some embodiments, a size of the alignment marks 210 may be equal to or less than about 2.5 µm, about 2 µm to about 2.5 µm, or equal to or less than about 0.5 µm.

In some embodiments, the semiconductor substrate 20A may include Si, Ge, SiGe, SiC, or other semiconductor materials. The semiconductor substrate 20A may be a bulk substrate or constructed as an SOI substrate. The semiconductor substrate 20A may include an RDL, a dielectric structure, or a combination thereof. The RDL may include conductive layers and/or conductive vias. The bonding layer 220 may be configured to be hybrid-bonded or fusion-bonded to another bonding layer (e.g., the bonding layer 120). In some embodiments, the bonding layer 220 includes silicon oxide, silicon oxynitride, or any suitable materials configured for hybrid bonding or fusion bonding. In some embodiments, the bonding layer 220 includes an RDL including conductive layers and/or conductive vias. The RDL of the bonding layer 220 may include the one or more alignment marks 210.

The pick-and-place tool 30 may include a pick-up head, e.g., a vacuum head that is capable of picking up a die through vacuum. In some embodiments, the pick-and-place tool 30 includes an IR detection device 310. In some embodiments, the IR detection device 310 is installed on the pick-up head of the pick-and-place tool 30. In some embodiments, the pick-up head of the pick-and-place tool 30 is attached to or equipped with the IR detection device 310 in a fixed relationship (e.g., so that a fixed spatial relation is present between the vacuum head and the IR detection device 310 during operation of the pick-and-place tool). In some embodiments, the IR detection device 310 includes one or more IR emitters and one or more IR detectors. The IR one or more IR emitters are configured to emit an IR light (e.g., electromagnetic radiation having a wavelength of between approximately 780 nm and approximately 1 mm), and the one or more IR detectors are configured to detect a reflected IR light generated by the emitted IR light reflected by an object (e.g., the alignment marks 110 and 210). In some embodiments, the pick-and-place tool 30 is coupled to a processing unit 40. In some embodiments, the processing unit 40 is connected to and configured to control the functions of the IR detection device 310 and the pick-up head of the pick-and-place tool 30. For example, the processing unit 40 may be configured to control movement of the pick-and-place tool 30 and/or send signals to and receive signals from the IR detection device 310.

Referring to FIG. 1B, the die 20 may be moved towards the wafer 10 at the initial speed V1 (or the first speed) until the die 20 is at a predetermined position that is separated from the wafer 10 by a predetermined distance D2. Alignment of the die 20 with the wafer 10 may start when the die 20 reaches the predetermined position. The predetermined distance D2 may be a minimum distance that provides a tolerance preventing the die 20 from colliding onto the wafer 10. In some embodiments, the predetermined distance D2 is equal to or greater than about 0.5 mm, greater than about 0.7 mm, greater than about 0.3 mm, about 0.5 mm, or other similar values. In some embodiments, aligning the die 20 with the wafer 10 may be performed when the die 20 stops moving in the direction of arrow DR1 (e.g., vertically stays at the predetermined position). In some other embodiments, aligning the die 20 with the wafer 10 may be performed as the die 20 keeps moving towards the wafer 10 in the direction of arrow DR1. In some embodiments, the die 20 may be moved towards the wafer 10 by way of a translation element (not shown) that is configured to move the pick-up head (e.g., the vacuum head that is capable of picking up a die through vacuum). In some embodiments, the translation element may comprise one or more actuators and/or motors coupled to the pick-up head.

Still referring to FIG. 1B, the die 20 may be aligned with the wafer 10 by using the IR detection device 310 of the pick-and-place tool 30. In some embodiments, a positional relationship (also referred to as “a first positional relationship”) between one or more sets of alignment marks including alignments marks respectively on the wafer 10 and the die 20 is obtained by using the IR detection device 310 of the pick-and-place tool 30. In some embodiments, a positional relationship between the alignment mark 110 and the alignment mark 210 is obtained by using the IR detection device 310 of the pick-and-place tool 30. In some embodiments, the positional relationship includes a position of the 2D pattern of the alignment mark 110 and a position of the 2D pattern of the alignment mark 210 related to the position of the 2D pattern of the alignment mark 110. In some embodiments, the positional relationship includes a misalignment of the 2D patterns of the alignment mark 110 and the alignment mark 210. In some embodiments, the positional relationship includes a misalignment of edges of the 2D patterns of the alignment mark 110 and the alignment mark 210. In some embodiments, the positional relationship includes a misalignment condition or a misalignment level of the 2D patterns of the alignment mark 110 and the alignment mark 210. In some embodiments, the positional relationship includes an offset between the positions of the 2D patterns of the alignment mark 110 and the alignment mark 210. In some embodiments, the alignment mark 110 and the alignment mark 210 each includes a 2D pattern in the X-Y plane, and the positional relationship includes a misalignment of the 2D patterns as view in a Z direction. In some embodiments, the IR detection device 310 may detect the positions of the alignment mark 110 and the alignment mark 210 one by one to obtain the positional relationship. In some embodiments, the IR detection device 310 may detect the positions of the alignment mark 110 and the alignment mark 210 simultaneously to obtain the positional relationship.

Still referring to FIG. 1B, the die 20 may be moved by the pick-and-place tool 30 from the predetermined position towards the wafer 10 at a different speed V2 (also referred to as “a second speed”) which is less than the initial speed V1. In some embodiments, the die 20 may stop at the predetermined position for obtaining the positional relationship and then continue the movement in the direction of arrow DR1 at the speed V2. In some other embodiments, the IR detection device 310 starts obtaining the positional relationship while the die 20 reaches the predetermined position, and the die 20 continues the movement in the direction of arrow DR1 at the speed V2 after passing the predetermined position while aligning the die 20 with the wafer 10 using the IR detection device 310 continues.

Next, referring to FIGS. 1C and 1D, FIG. 1D illustrating a top view of FIG. 1C, the die 20 may be aligned with the wafer 10 by the pick-and-place tool 30 according to the positional relationship. In some embodiments, the processing unit 40 is configured to generate a position correction instruction (also referred to as “a first position correction instruction”) based on the positional relationship. In some embodiments, the position correction instruction is sent to the pick-and-place tool 30. In some embodiments, a position of the die 20 is adjusted, by the pick-and-place tool 30, to an aligned position based on the position correction instruction received from the processing unit 40.

Still referring to FIGS. 1C and 1D, in some embodiments, the die 20 may be moved in a direction of arrow DR2 (i.e., along an X-axis) or a direction opposite to the direction of arrow DR2 to be adjusted to an aligned position (also referred to as “a first aligned position”). In some embodiments, the die 20 may be moved in a direction of arrow DR3 (i.e., along a Y-axis) or a direction opposite to the direction of arrow DR3 to be adjusted to the aligned position (or the first aligned position).

Still referring to FIGS. 1C and 1D, after the die 20 reaches the aligned position (or the first aligned position), another positional relationship (also referred to as “a second positional relationship”) between the alignment mark 110 and the alignment mark 210 may be obtained by using the IR detection device 310 of the pick-and-place tool 30. Next, the positional relationship (or the second positional relationship) may be received by the processing unit 40, and the processing unit 40 is configured to determine whether the positional relationship (or the second positional relationship) satisfies an alignment criteria.

Still referring to FIGS. 1C and 1D, if the positional relationship (or the second positional relationship) satisfies the alignment criteria, the manufacturing process may continue to a next step in which the die 20 is moved towards the wafer 10 for bonding, which will be discussed hereinafter in details. If the positional relationship (or the second positional relationship) fails to satisfy the alignment criteria, the processing unit 40 may be configured to generate another position correction instruction (also referred to as “a second position correction instruction”) based on the positional relationship (or the second positional relationship), and a position of the die 20 may be further adjusted to another aligned position (also referred to as “a second alignment position”) based on the position correction instruction (or the second position correction instruction) received from the processing unit 40. In some embodiments, the position correction instruction (or the second position correction instruction) is sent to the pick-and-place tool 30. In some embodiments, the position of the die 20 is moved by the pick-and-place tool 30 in the directions along the X-axis and/or the directions along the Y-axis to be adjusted to the aligned position (or the second alignment position).

In some embodiments, IR light is emitted from the IR detection device 310 of the pick-and-place tool 30 through the die 20 and the wafer 10 and reflected IR light is then received by the IR detection device 310 in order to check the alignment of the alignment mark 210 and the alignment mark 110. This information of positional relationship may then be passed or transmitted to the processing unit 40 in order to perform corrections and generate a position correction instruction that is desired for adjusting the position of the die 20 prior to the completed bonding of the die 20 and the wafer 10. In some embodiments, the IR light passes through the semiconductor material(s) and the dielectric material(s) of the die 20 and the wafer 10, while the alignment marks 110 and 210 are made of metal that reflects IR light and thus can provide position information of the alignment marks 110 and 210 with the reflected IR light.

In some embodiments, the step of obtaining a positional relationship between the alignment marks 110 and 210, the step of determining whether the obtained positional relationship satisfy an alignment criteria, and the step of adjusting the position of the die 20 to an updated aligned position based on a position correction instruction generated based on the obtained positional relationship may be repeated multiple times if the obtained positional relationship keeps failing to satisfy the alignment criteria. The die 20 may be moved to bond to the wafer 10 until the obtained positional relationship satisfies the alignment criteria. In some embodiments, the die 20 is moved to bond to the wafer 10 until the die 20 reaches an aligned position which satisfies the alignment criteria. In some embodiments, the die 20 is then moved by the pick-and-place tool 30 towards the wafer 10 for bonding at the speed V2 after aligning the die 20 to the wafer 10. In some embodiments, alignment of the die 20 is performed while moving the die 20 towards the wafer 10 (e.g., before moving the die 20 towards the wafer 10 is completed). In some such embodiments, alignment of the die 20 may start after the pick-and-place tool 30 starts to move the die 20 towards the wafer 10, and the alignment of the die 20 is completed before moving the die 20 towards the wafer 10 is completed. In some embodiments, moving the die 20 towards the wafer 10 and aligning the die 20 with the wafer 10 are performed simultaneously.

In some embodiments, the positional relationship (or the second positional relationship) includes a position of the 2D pattern of the alignment mark 110 and a position of the 2D pattern of the alignment mark 210 related to the position of the 2D pattern of the alignment mark 110. In some embodiments, the positional relationship (or the second positional relationship) includes a misalignment of the 2D patterns of the alignment mark 110 and the alignment mark 210. In some embodiments, the positional relationship (or the second positional relationship) includes a misalignment of edges of the 2D patterns of the alignment mark 110 and the alignment mark 210. In some embodiments, the positional relationship (or the second positional relationship) includes a misalignment condition or a misalignment level of the 2D patterns of the alignment mark 110 and the alignment mark 210. In some embodiments, the positional relationship (or the second positional relationship) includes a misalignment of the 2D patterns as view in a Z direction.

In some embodiments, the alignment criteria includes a minimum misalignment condition or misalignment level of the 2D patterns of the alignment mark 110 and the alignment mark 210 which allows the die 20 to bond to the wafer 10 with a satisfactory alignment. In some embodiments, the alignment criteria includes a minimum distance between edges of the 2D patterns of the alignment mark 110 and the alignment mark 210. In some embodiments, the alignment criteria includes a minimum offset between the positions of the 2D patterns of the alignment mark 110 and the alignment mark 210.

Referring to FIG. 1E, the die 20 may be bonded to the wafer 10 by the pick-and-place tool 30. In some embodiments, the die 20 is brought from the aligned position (i.e., the alignment position which satisfies the alignment criteria) into contact with the wafer 10 by the pick-and-place tool 30, and a bonding process may be performed on the die 20 and the wafer 10. In some embodiments, the die 20 is moved towards the wafer 10 in the direction of arrow DR1 by the pick-and-place tool 30.

In some embodiments, moving the die 20 towards the wafer 10 and aligning the die 20 with the wafer 10 may be performed simultaneously. In some embodiments, moving the die 20 towards the wafer 10 continues when aligning the die 20 to the wafer 10 is completed. In some embodiments, the die 20 is moved towards the wafer 10 in the direction of arrow DR1 while the die 20 is moved in the directions along the X-axis and/or the directions along the Y-axis to be adjusted to the aligned position (or the second alignment position) in an aligning process.

In some embodiments, the die 20 is moved towards the wafer 10 at the second speed V2 concurrent to detecting alignment mark 110 and alignment mark 210 and/or aligning the die 20 with the wafer 10. In some such embodiments, throughput of the pick-and-place tool 30 may be optimized by moving the die 20 to the predetermined position at the first speed V1 and then after reaching the predetermined position performing the alignment process while moving the die 20 at the second speed V2. In other embodiments, the die 20 may be moved to the predetermined position at the first speed V1, stopped to detect alignment mark 110 and alignment mark 210, and then moved at the second speed V2 during alignment of the die 20 with the wafer 10.

In some other embodiments, the die 20 stops moving vertically and vertically stays at the predetermined position when aligning the die 20 to the wafer 10 starts. In some embodiments, the die 20 is moved towards the wafer 10 for bonding after aligning the die 20 to the wafer 10 is completed.

In some embodiments, alignment mark 110 and the alignment mark 210 may be detected simultaneously. In other embodiments, alignment mark 110 and the alignment mark 210 may be detected sequentially (e.g., one after another). In some embodiments, the IR detection device 310 may be used to detect alignment mark 210 at the speed V2, then the pick-and-place tool 30 may stop to detect alignment mark 110 (or vice versa), and then the pick-and-place tool 30 may resume movement at the speed V2.

In some embodiments, the bonding process may include pressing the die 20 towards the wafer 10 and heating the die 20 and the wafer 10. In some embodiments, the bonding layer 120 of the wafer 10 is hybrid-bonded to the bonding layer 220 of the die 20. In some embodiments, the bonding layer 120 of the wafer 10 is fusion-bonded to the bonding layer 220 of the die 20. In some embodiments, the alignment mark 110 of the wafer 10 overlaps the alignment mark 210 of the die 20 from a top view perspective (i.e., as viewed in the Z direction). In some embodiments, the alignment mark 110 of the wafer 10 contacts the alignment mark 210 of the die 20 at an interface between the wafer 10 and the die 20.

Referring to FIG. 1F, the pick-and-place tool 30 may be removed from the die 20 after the bonding process is completed. As such, a semiconductor structure 1A is formed.

In some cases where a die is aligned to a wafer or package substrate prior to bonding, an external optical detector configured to detect visible light (e.g., a CCD) may be transferred to a detection location between the die and the wafer to detect the positions of the die and the wafer for alignment. After the detection and the alignment are completed, the optical detector is moved away from the detection location between the die and the wafer before bonding the die to the wafer. Moving the external optical detector in and out takes a significant time which may adversely affect the efficiency and the throughput of the bonding process of the die and the wafer.

According to some embodiments of the present disclosure, the alignment of the die with the wafer is performed by using an IR detection device installed on a pick-and-place tool. The IR detection device emits and detects IR light which transmits through semiconductor materials and dielectric materials, and thus the IR detection device can be installed on the pick-and-place tool and moved along with the pick-and-place tool. Moreover, the penetration depth of the IR detection device may be adjustable and may cover a range that exceeds the predetermined distance which provides a tolerance preventing the die from colliding onto the wafer. Therefore, the alignment of the die with the wafer can be performed by using the IR detection device in the process of the die being moved towards the wafer by the pick-and-place tool, the time used to move an external optical detector in and out of a detection location between the die and the wafer can be saved, and thus the efficiency and the throughput of the bonding process of the die and the wafer can be improved.

In addition, according to some embodiments of the present disclosure, the die and the wafer are aligned with each other by aligning the alignment marks having 2D patterns. The 2D patterns of the alignment marks can overlap in directions along the X-axis and the Y-axis (e.g., in an X-Y plane), and such overlay of 2D patterns provide a relatively accurate positional relationship between the alignment marks, and thus a relatively accurate position correction instruction can be generated based on the positional relationship. Therefore, the alignment of the die and the wafer can be relatively accurate in the X-Y plane.

In some cases where a die or wafer is bonded to another die or wafer by micro bumps or C4 bumps, since the sizes of micro bumps or C4 bumps are relatively large (e.g., about 5 µm to about 10 µm), the bonding interfaces are relatively large, and thus the tolerance window for positional shifts in the bonding process through micro bumps or C4 bumps is usually relatively large. Therefore, bonding through micro bumps or C4 bumps is usually used in structures which do not have a high-density conductive structure. In such cases, the bonding is achieved by simply disposing one die or wafer onto another die or wafer without high alignment accuracy. In addition, since the alignment accuracy is relatively low, bonding processes that use micro bumps or C4 bumps do not require a high-resolution alignment mechanism, since it may increase the cost yet provide no further advantages to the bonded structure.

According to some embodiments of the present disclosure, hybrid bonding or fusion bonding is configured to form bonded structures having a high-density conductive structure (e.g., bonding pads having a size of equal to or less than about 2.5 µm, about 2 µm to about 2.5 µm, or equal to or less than about 0.5 µm), and thus the alignment accuracy is relatively high. In some embodiments, the IR detection device that can emit and detect IR light which transmits through semiconductor materials and dielectric materials is installed on the pick-and-place tool. Therefore, moving the die towards the wafer and aligning the die with the wafer can be performed simultaneously, and thus the efficiency and the throughput of the bonding process of the die and the wafer can be further improved.

Moreover, in some cases where an alignment process may be performed in the bonding process through micro bumps or C4 bumps, and a CCD camera for capturing images of alignment marks is usually equipped outside of the pick-and-place tool. Therefore, the alignments marks are usually arranged at positions outside of device regions and proximal to dicing edges of the die, and thus the images of the alignment marks can be captured by the CCD camera to perform the alignment. In such cases, the alignment marks are proximal to dicing edges of the die having relatively rough structures and less planar surfaces, which may significantly reduce the clarity and resolution of the alignment marks arranged thereon. Therefore, in addition to that the CCD camera is provided with a relatively low detection resolution compared to that of an IR detection, the alignment marks arranged on relatively rough structures and/or less planar surfaces may also significantly reduce the alignment accuracy.

According to some embodiments of the present disclosure, with the IR detection device installed on the pick-and-place tool that is capable of emitting and detecting IR light which transmits through semiconductor materials and dielectric materials, the alignment marks can be arranged proximal to or within the device regions of the die and the wafer. Therefore, the clarity and resolution of the alignment marks is relatively high, the aforesaid drawbacks can be mitigated or prevented, and thus the alignment accuracy can be increased.

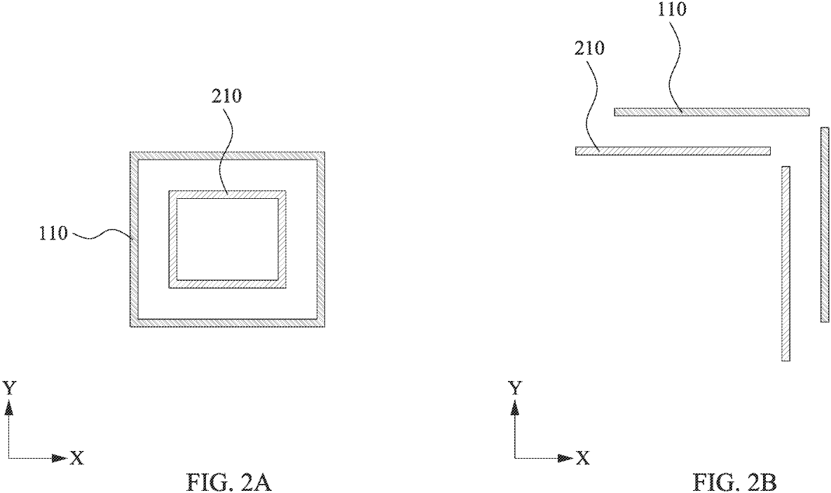

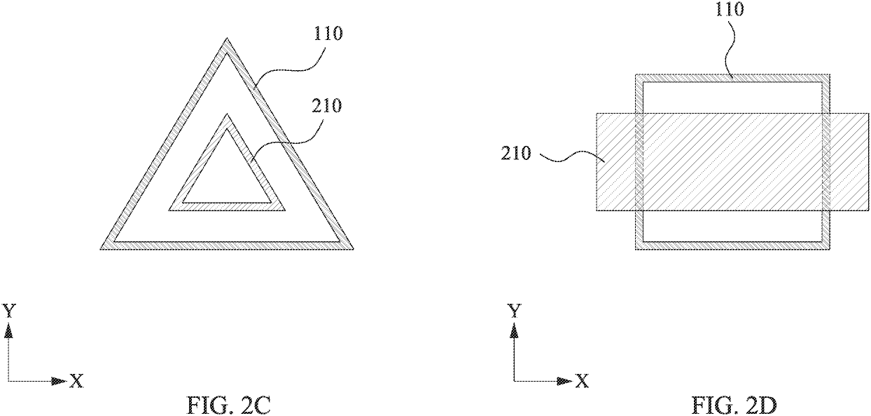

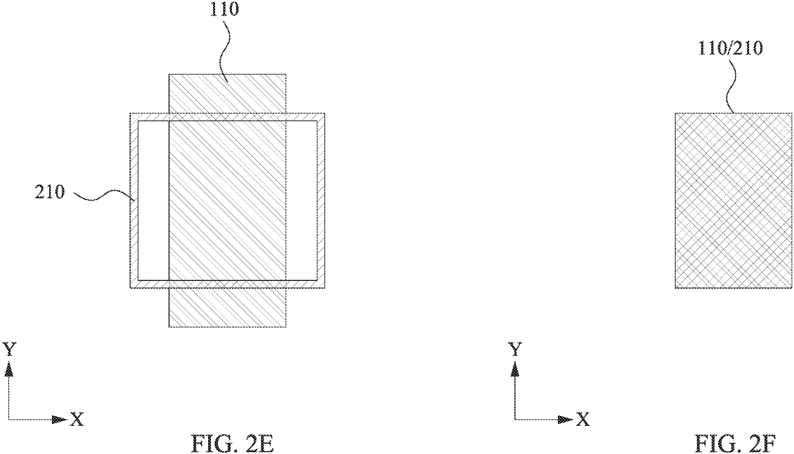

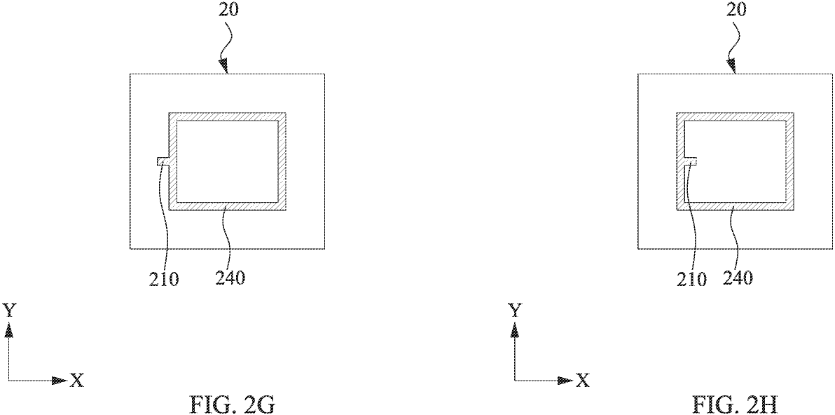

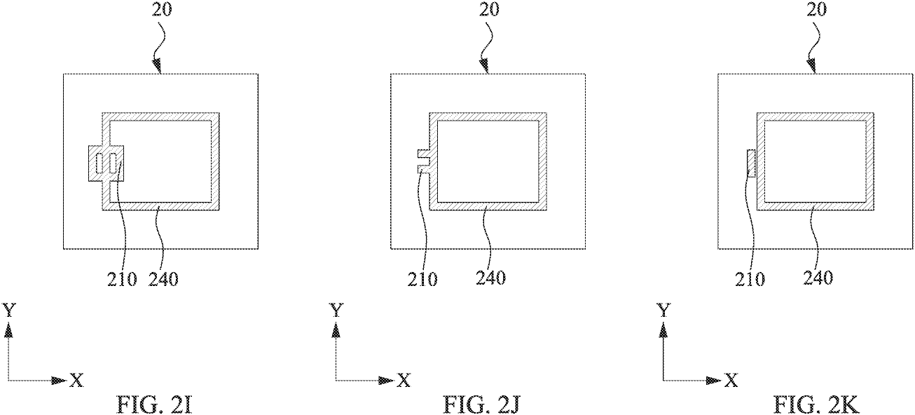

FIGS. 2A to 2K are top views of arrangements of alignment marks in accordance with some embodiments of the present disclosure.

Referring to FIG. 2A, the alignment mark 110 and the alignment mark 210 include frame patterns. In some embodiments, the alignment mark 210 is surrounded by the alignment mark 110 as viewed from a top view perspective (e.g., in the Z-axis). In some other embodiments, the alignment mark 110 may be surrounded by the alignment mark 210 (not shown in FIG. 2A). In some embodiments, edges of the alignment mark 110 are separated from edges of the alignment mark 210 by predetermined distances. In some embodiments, an alignment criteria for the positional relationship between the alignment marks 110 and 210 may include a minimum offset between the frame patterns of the alignment marks 110 and 210, a minimum distance between the edges of the alignment marks 110 and 210, or any suitable criteria that are within the contemplated scope of the disclosure.

Referring to FIG. 2B, the alignment mark 110 and the alignment mark 210 include a plurality of lines angled with each other (e.g., at a 90 degree angle). In some embodiments, lines of the alignment mark 110 are separated from lines of the alignment mark 210 by predetermined distances. In some embodiments, one or more lines of the alignment mark 110 are substantially parallel to one or more lines of the alignment mark 210. In some embodiments, an alignment criteria for the positional relationship between the alignment marks 110 and 210 may include a minimum distance between the lines of the alignment marks 110 and 210 or any suitable criteria that are within the contemplated scope of the disclosure.

Referring to FIG. 2C, the alignment mark 110 and the alignment mark 210 include frame patterns (e.g., triangle frame patterns). In some embodiments, the alignment mark 210 is surrounded by the alignment mark 110 as viewed from a top view perspective (e.g., in the Z-axis). In some other embodiments, the alignment mark 110 may be surrounded by the alignment mark 210 (not shown in FIG. 2A). In some embodiments, edges of the alignment mark 110 are separated from edges of the alignment mark 210 by predetermined distances. In some embodiments, an alignment criteria for the positional relationship between the alignment marks 110 and 210 may include a minimum offset between the frame patterns of the alignment marks 110 and 210, a minimum distance between the edges of the alignment marks 110 and 210, or any suitable criteria that are within the contemplated scope of the disclosure.

Referring to FIG. 2D, the alignment mark 110 includes a frame pattern, and the alignment mark 210 includes a rectangular shape pattern. In some embodiments, the alignment mark 210 overlaps the alignment mark 110 as viewed from a top view perspective (e.g., in the Z-axis). In some embodiments, edges of the alignment mark 110 are separated from edges of the alignment mark 210 by predetermined distances. In some embodiments, an alignment criteria for the positional relationship between the alignment marks 110 and 210 may include a minimum offset between the patterns of the alignment marks 110 and 210, a minimum distance between the edges of the alignment marks 110 and 210, or any suitable criteria that are within the contemplated scope of the disclosure.

Referring to FIG. 2E, the alignment mark 110 includes a rectangular shape pattern, and the alignment mark 210 includes a frame pattern. In some embodiments, the alignment mark 210 overlaps the alignment mark 110 as viewed from a top view perspective (e.g., in the Z-axis). In some embodiments, edges of the alignment mark 110 are separated from edges of the alignment mark 210 by predetermined distances. In some embodiments, an alignment criteria for the positional relationship between the alignment marks 110 and 210 may include a minimum offset between the patterns of the alignment marks 110 and 210, a minimum distance between the edges of the alignment marks 110 and 210, or any suitable criteria that are within the contemplated scope of the disclosure.

Referring to FIG. 2F, the alignment mark 110 and the alignment mark 210 include rectangular shape patterns. In some embodiments, the alignment mark 110 entirely overlaps the alignment mark 210. In other embodiments (not shown), the alignment mark 110 has edges that are offset from edges of the alignment mark 210. In some embodiments, an alignment criteria for the positional relationship between the alignment marks 110 and 210 may include a minimum offset between the patterns of the alignment marks 110 and 210, a minimum distance between the edges of the alignment marks 110 and 210, or any suitable criteria that are within the contemplated scope of the disclosure.

Referring to FIG. 2G, the die 20 may include a seal ring 240, and the seal ring 240 together with the alignment mark 210 can collectively function as an alignment mark. In some embodiments, the alignment mark 210 is connected to the seal ring 240 and protruded outwards from the seal ring 240. In some embodiments, the wafer 10 may include a structure having a seal ring connected to the alignment mark 110, which is similar to the structure illustrated in FIG. 2G.

Referring to FIG. 2H, the seal ring 240 together with the alignment mark 210 may collectively function as an alignment mark. In some embodiments, the alignment mark 210 is connected to the seal ring 240 and protruded towards a device region surrounded by the seal ring 240. In some embodiments, the wafer 10 may include a structure having a seal ring connected to the alignment mark 110, which is similar to the structure illustrated in FIG. 2H.

Referring to FIG. 2I, the seal ring 240 together with the alignment mark 210 may collectively function as an alignment mark. In some embodiments, the alignment mark 210 includes a frame pattern overlapping the seal ring 240 as viewed from a top view perspective (e.g., in the Z-axis). In some embodiments, the wafer 10 may include a structure having a seal ring connected to the alignment mark 110, which is similar to the structure illustrated in FIG. 2I.

Referring to FIG. 2J, the seal ring 240 together with the alignment mark 210 may collectively function as an alignment mark. In some embodiments, the alignment mark 210 includes a plurality of segments connected to the seal ring 240 and protruded outwards from the seal ring 240. In some embodiments, the wafer 10 may include a structure having a seal ring connected to the alignment mark 110, which is similar to the structure illustrated in FIG. 2J.

Referring to FIG. 2K, the seal ring 240 together with the alignment mark 210 may collectively function as an alignment mark. In some embodiments, the alignment mark 210 is spaced apart from the seal ring 240 and located outside of the device region surrounded by the seal ring 240. In some embodiments, the wafer 10 may include a structure having a seal ring spaced apart from the alignment mark 110, which is similar to the structure illustrated in FIG. 2K.

According to some embodiments of the present disclosure, a large 2D pattern (e.g., a large frame pattern) surrounding a small 2D pattern (e.g., a small frame pattern) can provide multiple alignments in multiple directions in the X-Y plane, and thus the alignment accuracy can be increased.

In addition, according to some embodiments of the present disclosure, measurements of distances between parallel lines of different alignment marks are relatively easy and accurate. Therefore, aligning parallel lines of different alignment marks according to the positional relationship obtained by the IR detection device can provide a relatively easy and accurate alignment.

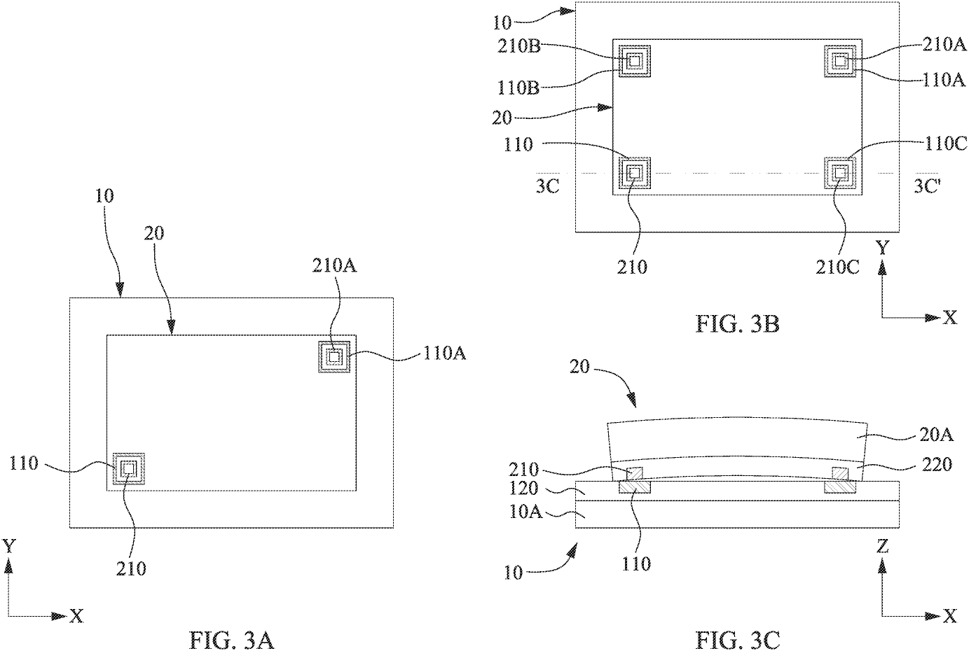

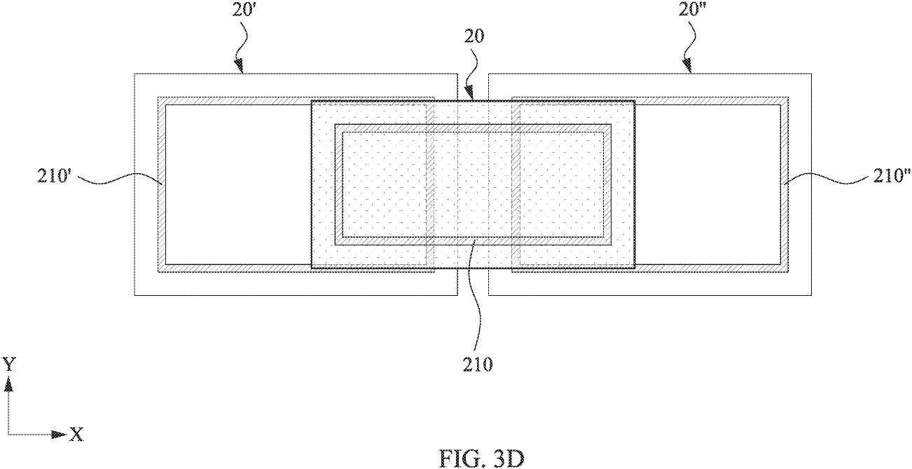

FIG. 3A is a top view of an arrangement of alignment marks in accordance with some embodiments of the present disclosure.

Referring to FIG. 3A, the die 20 includes a plurality of alignment marks (e.g., alignment marks 210 and 210A), and the wafer 10 includes a plurality of alignment marks (e.g., alignment marks 110 and 110A) each configured to align to one of the alignment marks of the die 20. In some embodiments, the alignment marks 210 and 210A are located at diagonal corner positions of the die 20. In some embodiments, the alignment marks 110 and 110A are located at positions corresponding to the alignment marks 210 and 210A, respectively (e.g., at diagonal corner positions of the wafer 10).

According to some embodiments of the present disclosure, two sets of alignment marks are located at diagonal corner position of the die, and thus alignment shifts resulted from rotation in X-Y plane (e.g., the die may rotate in the X-Y plane when moved by the pick-and-place tool) can be prevented. Therefore, the alignment accuracy can be improved.

FIGS. 3B to 3C are schematic views of arrangements of alignment marks in accordance with some embodiments of the present disclosure. In some embodiments, FIG. 3B is a top view, and FIG. 3C is a cross-sectional view along the cross-sectional line 3C-3C′ in FIG. 3B.

Referring to FIGS. 3B and 3C, the die 20 includes a plurality of alignment marks (e.g., alignment marks 210, 210A, 210B, and 210C), and the wafer 10 includes a plurality of alignment marks (e.g., alignment marks 110, 110A, 110B, and 110C) each configured to align to one of the alignment marks of the die 20. In some embodiments, the alignment marks 210, 210A, 210B, and 210C are located at four corner positions of the die 20. In some embodiments, the alignment marks 110, 110A, 110B, and 110C are located at positions corresponding to the alignment marks 210, 210A, 210B, and 210C, respectively (e.g., at four corner positions of the wafer 10).

FIG. 3D is a top view of an arrangement of alignment marks in accordance with some embodiments of the present disclosure.

Referring to FIG. 3D, the die 20 may be stacked over the dies 20′ and 20″ and electrically connect the die 20′ to the die 20″. In some embodiments, each of the dies 20, 20′ and 20″ includes an alignment mark (e.g., alignment marks 210, 210′, and 210″), and the alignment mark 210 is aligned to the alignment marks 210′ and 210″. In some embodiments, the alignment marks 210, 210′, and 210″ may be seal rings of the dies 20, 20′, and 20″.

According to some embodiments of the present disclosure, four sets of alignment marks are located at four corner positions of the die, and thus alignment shifts resulted from bending or warpage of the die can be prevented. Therefore, a three-dimensional alignment correction may be provided, and thus the alignment accuracy can be improved.

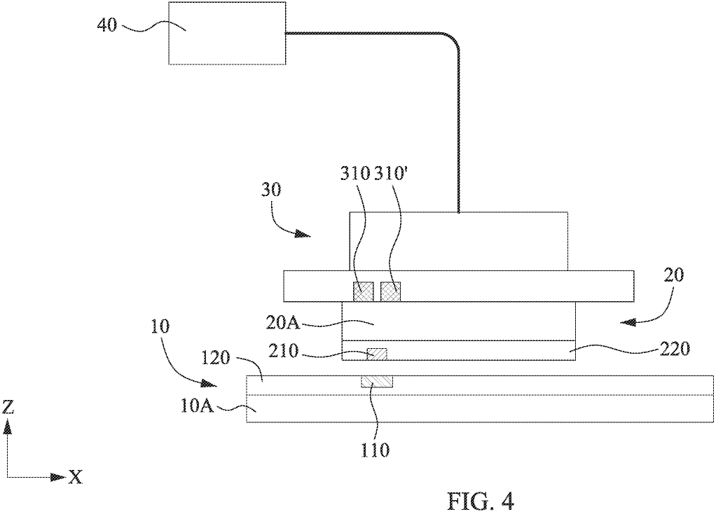

FIG. 4 is a schematic view of one or more intermediate stages of a method of manufacturing a semiconductor structure in accordance with some embodiments of the present disclosure.

Referring to FIG. 4, the pick-and-place tool 30 includes IR detection devices 310 and 310′. In some embodiments, the IR detection devices 310 and 310′ are installed on the pick-up head of the pick-and-place tool 30. In some embodiments, the pick-up head of the pick-and-place tool 30 is attached to or equipped with the IR detection devices 310 and 310′ in a fixed relationship. In some embodiments, the IR detection devices 310 and 310′ are connected to the processing unit 40. The processing unit 40 is configured to process the positional information received from the IR detection devices 310 and 310′. In some embodiments, each of the IR detection devices 310 and 310′ includes an IR emitter and an IR detector. The IR emitter is configured to emit an IR light, and the IR detector is configured to detect a reflected IR light generated by the emitted IR light reflected by an object.

In some embodiments, the IR detection device 310 is configured to detect a position of the alignment mark 110, and the IR detection device 310′ is configured to detect a position of the alignment mark 210, so as to obtain the positional relationship. In some embodiments, the IR detection device 310 and the IR detection device 310′ are configured to detect the positions of the alignment marks 110 and 210 simultaneously to obtain the positional relationship. Obtaining the positions of alignment marks 110 and 210 simultaneously allows for the pick-and-place tool 30 to increase through-put. In some embodiments, the IR detection devices 310 and 310′ have different penetration depths. In some embodiments, the IR detection device 310 and the IR detection device 310′ each has a penetration depth configured for detecting the alignment mark 110 and the alignment mark 210, respectively.

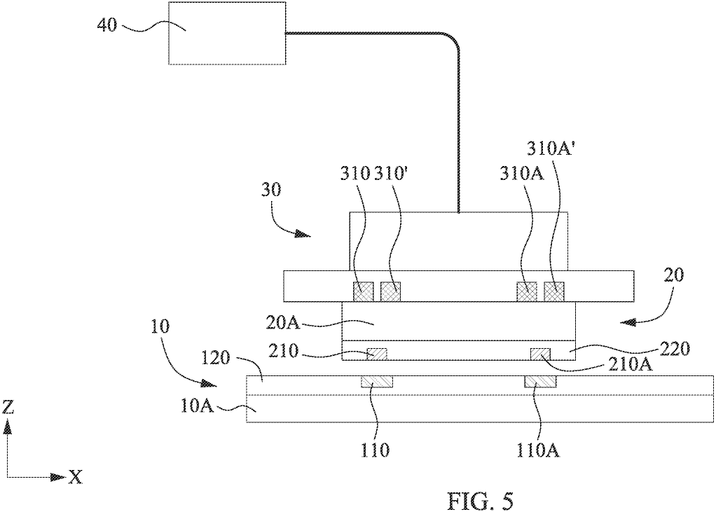

FIG. 5 is a schematic view of one or more intermediate stages of a method of manufacturing a semiconductor structure in accordance with some embodiments of the present disclosure.

Referring to FIG. 5, the pick-and-place tool 30 includes IR detection devices 310, 310′, 310A, and 310A′. In some embodiments, the IR detection devices 310, 310′, 310A, and 310A′ are installed on the pick-up head of the pick-and-place tool 30. In some embodiments, the pick-up head of the pick-and-place tool 30 is attached to or equipped with the IR detection devices 310, 310′, 310A, and 310A′ in a fixed relationship. In some embodiments, the IR detection devices 310, 310′, 310A, and 310A′ are connected to the processing unit 40. The processing unit 40 is configured to process the positional information received from the IR detection devices 310, 310′, 310A, and 310A′. In some embodiments, each of the IR detection devices 310, 310′, 310A, and 310A′ includes an IR emitter and an IR detector. The IR emitter is configured to emit an IR light, and the IR detector is configured to detect a reflected IR light generated by the emitted IR light reflected by an object.

In some embodiments, the IR detection device 310 is configured to detect a position of the alignment mark 110, the IR detection device 310′ is configured to detect a position of the alignment mark 210, the IR detection device 310A is configured to detect a position of the alignment mark 110A, the IR detection device 310A′ is configured to detect a position of the alignment mark 210A, so as to obtain the positional relationship. In some embodiments, the 310, 310′, 310A, and 310A′ are configured to detect the positions of the alignment marks 110, 210, 110A, and 210A simultaneously to obtain the positional relationship. In some embodiments, the IR detection devices 310 and 310′ have different penetration depths, and the IR detection devices 310A and 310A′ have different penetration depths. In some embodiments, the IR detection device 310 and the IR detection device 310′ each has a penetration depth configured for detecting the alignment mark 110 and the alignment mark 210, respectively. In some embodiments, the IR detection device 310A and the IR detection device 310A′ each has a penetration depth configured for detecting the alignment mark 110A and the alignment mark 210A, respectively.

According to some embodiments of the present disclosure, the processing unit may be configured to process the positional information received from multiple IR detection devices simultaneously, and thus the processing unit can generate the positional correction instruction based on the positional relationship between multiple sets of alignment marks or from multiple IR detection devices. Therefore, the alignment accuracy can be improved without increasing processing time or detection time.

FIG. 6 is a cross-sectional view of a semiconductor structure 1 in accordance with some embodiments of the present disclosure.

Referring to FIG. 6, the semiconductor structure 1 may include a wafer 10 and a die 20. In some embodiments, the die 20 is bonded to the wafer 10.

The wafer 10 may be or include a package substrate or a package substrate strip including a plurality of package substrates. In some embodiments, the wafer 10 may be or include a device structure including one or more devices in one or more package structures. In some embodiments, the wafer 10 includes a semiconductor substrate 10A, a bonding layer 10B, and one or more alignment marks 110. In some embodiments, the bonding layer 10B is on the semiconductor substrate 10A, and the one or more alignment marks 110 are in the bonding layer 10B.

In some embodiments, the semiconductor substrate 10A may include Si, Ge, SiGe, SiC, or other proper semiconductor materials. The semiconductor substrate 10A may be a bulk substrate or constructed as a semiconductor on an SOI substrate. The semiconductor substrate 10A may include an RDL, a dielectric structure, or a combination thereof. The RDL may include conductive layers and/or conductive vias.

In some embodiments, the alignment mark 110 includes metal. The metal may be configured to reflect IR light (e.g., IR light emitted from the IR detection device 310 of the pick-and-place tool 30). The alignment mark 110 may include Cu, Al, Au, or any other suitable materials configured to reflect IR light that are within the contemplated scope of the disclosure. In some embodiments, the alignment mark 110 includes a 2D pattern in an X-Y plane. In some embodiments, the alignment mark 110 includes a dummy metal pattern. In some embodiments, the alignment mark 110 includes a rectangular shape pattern, a polygonal shape pattern, an irregular shape pattern, a frame pattern, a pattern formed of a plurality of lines angled with each other, or a combination thereof.

The bonding layer 10B may be configured to be hybrid-bonded or fusion-bonded to another bonding layer. In some embodiments, the bonding layer 10B includes a dielectric layer 130 and an RDL including one or more circuit layers 126, one or more conductive vias 124, and one or more bonding pads (also referred to as “hybrid bond pads”) 122 in the dielectric layer 130. In some embodiments, the RDL of the bonding layer 10B may include the alignment mark 110. In some embodiments, the bonding pads 122 and the alignment mark 110 may be formed collectively as a patterned metal layer. In some embodiments, the bonding pads 122 and the alignment mark 110 includes a same metal material. The dielectric layer 130 may include silicon oxide, silicon oxynitride, or any suitable dielectric materials.

The die 20 may be or include one or more integrated circuit devices such as transistors, diodes, resistors, capacitors, and/or the like. In some embodiments, the die 20 may be or include a device structure including one or more devices. In some embodiments, the die 20 includes a semiconductor substrate 20A, a bonding layer 20B, and one or more alignment marks 210. In some embodiments, the bonding layer 20B is on the semiconductor substrate 20A, and the one or more alignment marks 210 are in the bonding layer 20B.

In some embodiments, the semiconductor substrate 20A may include Si, Ge, SiGe, SiC, or other proper semiconductor materials. The semiconductor substrate 20A may be a bulk substrate or constructed as an SOI substrate. The semiconductor substrate 20A may include an RDL, a dielectric structure, or a combination thereof. The RDL may include conductive layers and/or conductive vias.

In some embodiments, the alignment mark 210 includes metal. The metal may be configured to reflect IR light (e.g., IR light emitted from the IR detection device 310 of the pick-and-place tool 30). The alignment mark 210 may include Cu, Al, Au, or any other suitable materials configured to reflect IR light that are within the contemplated scope of the disclosure. In some embodiments, the alignment mark 210 includes a 2D pattern in the X-Y plane. In some embodiments, the alignment mark 210 includes a dummy metal pattern. In some embodiments, the alignment mark 210 includes a rectangular shape pattern, a polygonal shape pattern, an irregular shape pattern, a frame pattern, a pattern formed of a plurality of lines angled with each other, or a combination thereof.

The bonding layer 20B may be configured to be hybrid-bonded or fusion-bonded to another bonding layer (e.g., the bonding layer 10B). In some embodiments, the bonding layer 20B includes a dielectric layer 230 and an RDL including one or more circuit layers 226, one or more conductive vias 224, and one or more bonding pads (also referred to as “hybrid bond pads”) 222 in the dielectric layer 230. The RDL of the bonding layer 20B is disposed on the semiconductor substrate 20A. In some embodiments, the RDL of the bonding layer 20B may be facing the wafer 10 and include the alignment mark 210. In some embodiments, the bonding pads 222 and the alignment mark 210 may be formed collectively as a patterned metal layer. In some embodiments, the bonding pads 222 and the alignment mark 210 includes a same metal material. The dielectric layer 230 may include silicon oxide, silicon oxynitride, or any suitable dielectric materials.

In some embodiments, the die 20 further includes a seal ring 240 surrounding a device region of the die 20. The seal ring 240 may be in the dielectric layer 230. In some embodiments, the seal ring 240 may comprise stacked metal interconnects. In some embodiments, the alignment mark 210 is disposed adjacent to the seal ring 240. In some embodiments, the alignment mark 210 is surrounded by or disposed inside the seal ring 240. In some embodiments, the alignment mark 210 is disposed within the device region of the die 20.

In some embodiments, the alignment mark 110 and the alignment mark 210 are at an interface between the die 20 and the wafer 10.

FIG. 6A is a cross-sectional view of a semiconductor structure 1A in accordance with some embodiments of the present disclosure. In some embodiments, the semiconductor structure 1A is similar to the semiconductor structure 1 in FIG. 6, with differences therebetween as follows. Descriptions of similar components are omitted.

In some embodiments, the die 20 does not include an alignment mark (e.g., the alignment mark 210 illustrated in FIG. 6). The seal ring 240 may serve as an alignment mark.

FIG. 6B is a cross-sectional view of a semiconductor structure 1B in accordance with some embodiments of the present disclosure. In some embodiments, the semiconductor structure 1B is similar to the semiconductor structure 1 in FIG. 6, with differences therebetween as follows. Descriptions of similar components are omitted.

In some embodiments, the wafer 10 does not include an alignment mark (e.g., the alignment mark 110 illustrated in FIG. 6). The seal ring 140 may serve as an alignment mark which aligns to an alignment mark (e.g., alignment mark 210 of FIG. 6) and/or the seal ring 240 in the bonding process to form the semiconductor structure 1B. In some embodiments, the seal ring 240 overlaps the seal ring 140 as viewed from a top view perspective (e.g., in the Z-axis). In some other embodiments (not shown), the seal ring 140 may be located directly under the device region surrounded by the seal ring 240 and free from overlapping the seal ring 240 from a top view perspective (e.g., in the Z-axis).

FIG. 6C is a cross-sectional view of a semiconductor structure 1C in accordance with some embodiments of the present disclosure. In some embodiments, the semiconductor structure 1C is similar to the semiconductor structure 1 in FIG. 6, with differences therebetween as follows. Descriptions of similar components are omitted.

In some embodiments, the wafer 10 does not include an alignment mark (e.g., the alignment mark 110 illustrated in FIG. 6). The seal ring 140 may serve as an alignment mark which aligns to the alignment mark 210 and/or the seal ring 240 in the bonding process to form the semiconductor structure 1C. In some embodiments, the seal ring 140 is free from overlapping the seal ring 240 and the device region surrounded by the seal ring 240 from a top view perspective (e.g., in the Z-axis).

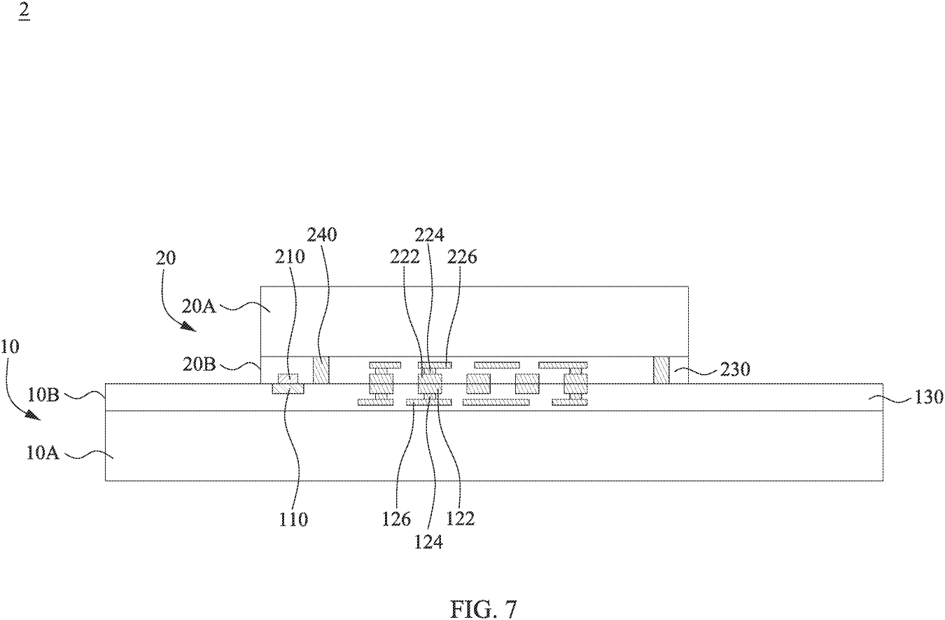

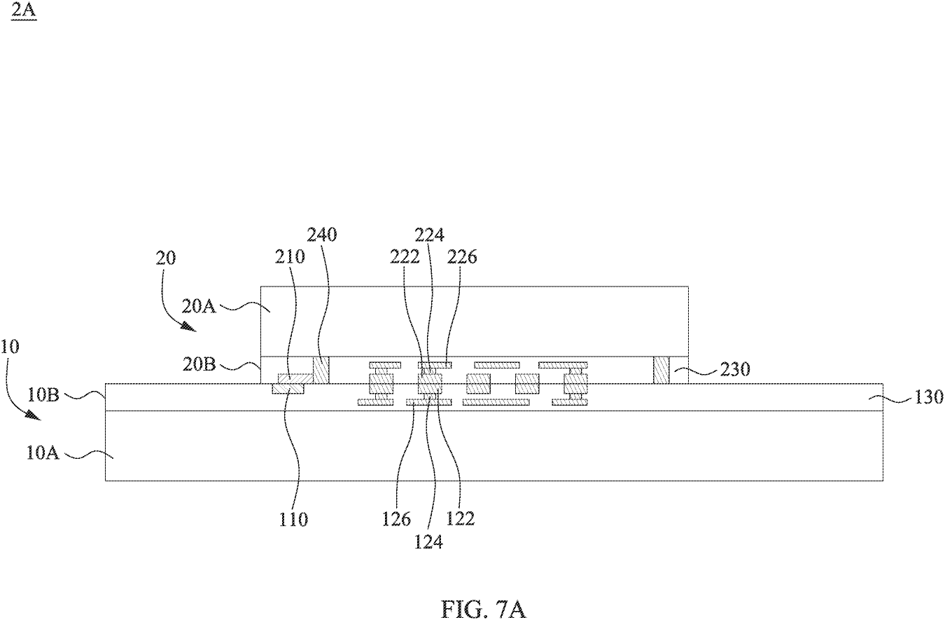

FIG. 7 is a cross-sectional view of a semiconductor structure 2 in accordance with some embodiments of the present disclosure. In some embodiments, the semiconductor structure 2 is similar to the semiconductor structure 1 in FIG. 6, with differences therebetween as follows. Descriptions of similar components are omitted.

Referring to FIG. 7, in some embodiments, the alignment mark 210 is disposed outside of the seal ring 240. In some embodiments, the alignment mark 210 is disposed outside of the device region of the die 20.

FIG. 7A is a cross-sectional view of a semiconductor structure 2A in accordance with some embodiments of the present disclosure. In some embodiments, the semiconductor structure 2A is similar to the semiconductor structure 2 in FIG. 7, with differences therebetween as follows. Descriptions of similar components are omitted.

In some embodiments, the alignment mark 210 is connected to the seal ring 240 and collectively function as an alignment mark. The alignment mark 210 and the seal ring 240 may have a structure similar to the structure illustrated in FIG. 2G.

Some embodiments of the present disclosure provide a method of manufacturing a semiconductor structure. The method includes following operations: moving a die towards a wafer by a pick-and-place tool, the pick-and-place tool comprising an infrared (IR) detection device attached to the pick-and-place tool in a fixed relationship; aligning the die with the wafer by using the IR detection device; and bonding the die to the wafer.

Some embodiments of the present disclosure provide a method of manufacturing a semiconductor structure. The method includes following operations: providing a pick-and-place tool comprising an IR detection device; obtaining a positional relationship between a first alignment mark on a first device structure and a second alignment mark on a second device structure by using the IR detection device of the pick-and-place tool; and aligning the first device structure with the second device structure by the pick-and-place tool according to the positional relationship.

Some embodiments of the present disclosure provide a semiconductor structure. The semiconductor structure includes a die and a package substrate. The die includes a first alignment mark. The package substrate is bonded to the die. The package substrate includes a second alignment mark. The first alignment mark and the second alignment mark are at an interface between the die and the package substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor structure, comprising:
moving a die towards a wafer by a pick-and-place tool, the pick-and-place tool comprising an infrared (IR) detection device attached to the pick-and-place tool in a fixed relationship;
aligning the die with the wafer by using the IR detection device, ; and
bonding the die to the wafer.

2. The method of claim 1, wherein the die comprises a first alignment mark, the wafer comprises a second alignment mark, and aligning the die with the wafer comprises:
obtaining a positional relationship between the first alignment mark and the second alignment mark by using the IR detection device; and
generating a position correction instruction, using a processing unit, based on the positional relationship.

3. The method of claim 2, wherein aligning the die with the wafer further comprises:
adjusting a position of the die to an aligned position based on the position correction instruction received from the processing unit.

4. The method of claim 3, wherein bonding the die to the wafer comprises:
bringing the die from the aligned position into contact with the wafer by the pick-and-place tool.

5. The method of claim 2, wherein the first alignment mark and the second alignment mark comprise metal configured to reflect IR light.

6. The method of claim 1, wherein moving the die towards the wafer comprises:
moving the die towards the wafer at a first speed until the die is at a predetermined position that is separated from the wafer by a predetermined distance; and
moving the die from the predetermined position towards the wafer at a second speed less than the first speed.

7. The method of claim 6, wherein aligning the die with the wafer starts when the die reaches the predetermined position.

8. A method of manufacturing a semiconductor structure, comprising:
providing a pick-and-place tool comprising a first IR detection device;
obtaining a positional relationship between a first alignment mark on a first device structure and a second alignment mark on a second device structure by using the first IR detection device of the pick-and-place tool; and
aligning the first device structure with the second device structure by the pick-and-place tool according to the positional relationship.

9. The method of claim 8, further comprising bonding the first device structure to the second device structure.

10. The method of claim 8, further comprising moving the first device structure to a predetermined position at a first speed prior to aligning the first device structure with the second device structure, wherein aligning the first device structure with the second device structure comprises moving the first device structure by the pick-and-place tool at a second speed less than the first speed.

11. The method of claim 8, wherein the first alignment mark and the second alignment mark comprise two-dimensional (2D) patterns, and the positional relationship comprises a misalignment of the 2D patterns of the first alignment mark and the second alignment mark.

12. The method of claim 8, wherein the pick-and-place tool further comprises a second IR detection device, and the first IR detection device and the second IR detection device are configured to detect a position of the first alignment mark and a position of the second alignment mark respectively to obtain the positional relationship.

13. The method of claim 12, wherein the first IR detection device and the second IR detection device are configured to detect the position of the first alignment mark and the position of the second alignment mark simultaneously to obtain the positional relationship.

14. The method of claim 8, wherein the first device structure comprises a plurality of first alignment marks that include the first alignment mark, the second device structure comprise a plurality of second alignment marks that include the second alignment mark, each of the plurality of second alignment marks configured to align to one of the plurality of first alignment marks, and the IR detection device comprises a plurality of IR detectors configured to detect positions of the plurality of first alignment marks and the plurality of second alignment marks to obtain the positional relationship.

15. A semiconductor structure, comprising:
a die comprising a first alignment mark; and
a package substrate bonded to the die and comprising a second alignment mark, wherein the first alignment mark and the second alignment mark are at an interface between the die and the package substrate.

16. The semiconductor structure of claim 15, wherein the first alignment mark and the second alignment mark comprise dummy metal patterns.

17. The semiconductor structure of claim 15, wherein each of the first alignment mark and the second alignment mark comprises a rectangular shape pattern, a polygonal shape pattern, an irregular shape pattern, a frame pattern, a pattern formed of a plurality of lines angled with each other, or a combination thereof.

18. The semiconductor structure of claim 15, wherein the die comprises a redistribution layer (RDL) facing the package substrate, and the RDL comprises the first alignment mark.

19. The semiconductor structure of claim 18, wherein the die further comprises a seal ring surrounding a device region of the die, and the first alignment mark is disposed adjacent to the seal ring.

20. The semiconductor structure of claim 18, wherein the die further comprises a semiconductor substrate, the RDL is disposed on the semiconductor substrate and further comprises a dielectric layer and a plurality of hybrid bond pads in the dielectric layer, and the first alignment mark and the hybrid bond pads comprise a same metal material.
